(19) United States
(12) Patent Application Publication
(10) Pub. No.: US 2025/0219611 A1
(43) Pub. Date: Jul. 3, 2025

(54) ACOUSTIC MULTILAYER FILM, HIGH FREQUENCY FILTER DEVICE, AND BULK ACOUSTIC WAVE FILTER DEVICE

(71) Applicant: NITTO DENKO CORPORATION, Ibaraki-shi, Osaka (JP)

(72) Inventors: Yuzuki AOKI, Ibaraki-shi, Osaka (JP); Daisuke NAKAMURA, Ibaraki-shi, Osaka (JP); Gaku TSUBURAOKA, Ibaraki-shi, Osaka (JP); Manami KUROSE, Ibaraki-shi, Osaka (JP); Hironobu MACHINAGA, Ibaraki-shi, Osaka (JP)

(21) Appl. No.: 18/851,345

(22) PCT Filed: Mar. 29, 2023
(86) PCT No.: PCT/JP2023/012784

§ 371 Date: Sep. 26, 2024

(30) Foreign Application Priority Data
Mar. 31, 2022 (JP) 2022-058814

(51) Int. Cl. H03H 9/02; H03H 9/17; H03H 9/54

(52) U.S. Cl. CPC H03H 9/02133; H03H 9/02157; H03H 9/175; H03H 9/54

(57) ABSTRACT

A stress-relaxed acoustic multilayer film, and a high frequency filter device using such a stress-relaxed acoustic multilayer film are provided. The acoustic multilayer film includes two or more pairs of a first layer and a second layer, the first layer having a first specific acoustic impedance, the second layer having a specific acoustic impedance lower than the first specific acoustic impedance, and the first layer and the second layer being alternately laminated on a support substrate, wherein at least one of the first layers of the acoustic multilayer film is divided in a laminated direction by a dividing layer.

### TECHNICAL FIELD

The present invention relates to an acoustic multilayer film, a high frequency filter device, and a bulk acoustic wave filter device.

### BACKGROUND ART

Use of high-frequency radio waves such as microwaves, millimeter waves, and terahertz waves enables high-speed broadband communications. According to the 5G mobile communication standard, a frequency band close to 6 GHZ, referred to as “sub-6”, and the 28 GHz-band are used, and future use of the 100 GHz-band is also studied. Thus, resonators and band-pass filters suited to high frequencies exceeding some gigahertz are demanded. For resonators of electronic devices such as smartphones and the like, and high-frequency filters of communication devices, BAW resonators utilizing Bulk Acoustic Waves (BAW) or BAW filters are used.

The BAW filter utilizes the piezoelectric effect of the piezoelectric layer interposed between the upper and lower electrodes to filter high frequencies. When the energy of resonance leaks to the substrate side during filtering, the wave reflected at the interface of the substrate adversely affects the resonance characteristics. In order to inhibit the leakage energy, an acoustic multilayer film in which a low acoustic impedance layer and a high acoustic impedance layer are alternately laminated is used as an acoustic mirror. In order to reduce the effect of the stress caused by the acoustic multilayer film, a method is known in which the acoustic multilayer film is divided in the in-plane direction by dicing and is separated into a plurality of regions (for example, see Patent Document 1). Further, a configuration is known in which an acoustic multilayer film is formed on one side of the substrate and a compressive stress film is provided on the opposite side of the substrate to offset the compressive stress generated by the acoustic multilayer (see, for example, Patent Document 2).

### CITATION LIST

### Patent Literature

Patent Document 1: Japanese Unexamined Patent Application Publication No. 2021-190794

Patent Document 2: Japanese Unexamined Patent Application Publication No. 2008-22408

### SUMMARY OF INVENTION

### Technical Problem

In the acoustic multilayer film, a metal thin film is used as a high acoustic impedance layer. In the 2 GHz band, the total thickness of the high acoustic impedance layer is 1 μm or more, and peeling from the substrate, cracking, and the like occur due to the surface roughness and the stress of the metal. In Patent Document 1, in order to relax such stress, the acoustic multilayer film is divided in the in-plane by dicing and is separated into a plurality of regions. There is concern that a residual diced film and re-adhesion of generated film fragments may cause electrode shorts and degradation of characteristics due to foreign matter when piezoelectric (or resonance) devices are formed.

In one aspect, an object of the present invention is to provide an acoustic multilayer film with reduced stress, and a high frequency filter device and a bulk acoustic wave filter device using such an acoustic multilayer film.

### Solution to Problem

According to an aspect of an embodiment, an acoustic multilayer film includes:
two or more pairs of a first layer and a second layer, the first layer having a first specific acoustic impedance, the second layer having a specific acoustic impedance lower than the first specific acoustic impedance, and the first layer and the second layer being alternately laminated on a support substrate,
wherein at least one of the first layers of the acoustic multilayer film is divided in a laminated direction by a dividing layer.

In a preferred configuration example, the dividing layer inserted in the first layer has an acoustic impedance lower than the first specific acoustic impedance.

### Advantageous Effects of Invention

According to the embodiment, a stress-relaxed acoustic multilayer film, and a high frequency filter device using such a stress-relaxed acoustic multilayer film are provided.

### BRIEF DESCRIPTION OF DRAWINGS

FIG. 1 is a schematic view of a laminate including an acoustic multilayer film of an embodiment.

FIG. 2 is a schematic view of a high frequency filter device using the acoustic multilayer film of FIG. 1.

FIG. 3 is a graph illustrating a relationship between the thickness of a dividing layer and filter characteristics.

FIG. 4A is a diagram illustrating a surface roughness of the acoustic multilayer film without the dividing layer.

FIG. 4B is a diagram illustrating the surface roughness of the acoustic multilayer film when the thickness of the dividing layer is 1 nm.

FIG. 4C is a diagram illustrating the surface roughness of the acoustic multilayer film when the thickness of the dividing layer is 2 nm.

FIG. 4D is a diagram illustrating the surface roughness of the acoustic multilayer film when the thickness of the dividing layer is 29 nm.

FIG. 5 is a diagram illustrating specifications and filter characteristics of acoustic multilayer films of Examples and Comparative Example.

FIG. 6 is a view illustrating the film forming conditions of an acoustic multilayer film.

### DESCRIPTION OF EMBODIMENTS

According to an embodiment, in order to relax the stress generated in an acoustic multilayer film, a dividing layer is inserted into at least one of the high acoustic impedance layers forming the acoustic multilayer film such that the high acoustic impedance layer is divided in a laminated direction. The dividing layer is preferably amorphous. The dividing layer may be made of a metal oxide, a metal nitride, a metal oxynitride, or the like. From the viewpoint of stress relaxation and maintenance of crystallinity of the acoustic multilayer film, the number of layers of the dividing layer inserted into the high acoustic impedance layer is preferably two or more. By inserting the dividing layers into the high acoustic impedance layer, the effect of the crystalline state of the base is reset, and the stress is relaxed. Since this configuration does not require any fabrication steps, a damage-free, stress-relaxed acoustic multilayer film can be formed. Thus, it is possible to maintain good resonance characteristics of a device to which the acoustic multilayer film is applied.

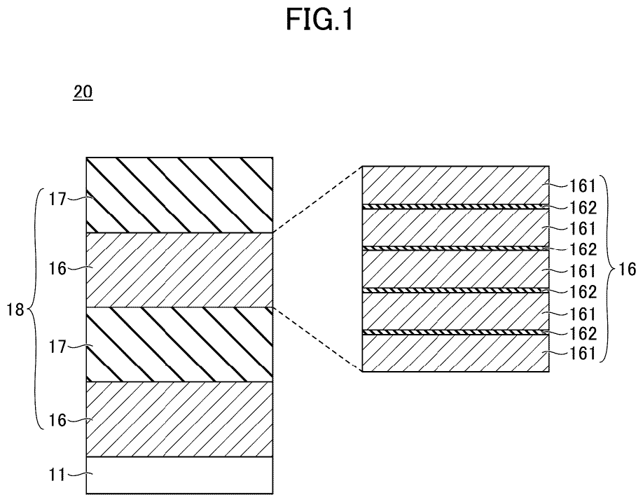

FIG. 1 is a schematic view of a laminate 20 including an acoustic multilayer film 18 according to the embodiment. The laminate 20 includes a support substrate 11 and an acoustic multilayer film 18 provided on the support substrate 11. The acoustic multilayer film 18 is formed by alternately laminating two or more pairs of a first layer 16 and a second layer 17. The first layer 16 has a predetermined specific acoustic impedance and the second layer 17 has a specific acoustic impedance lower than that of the first layer 16. Since the first layer 16 has a higher specific acoustic impedance than the second layer 17, the first layer is referred to as a “high acoustic impedance layer 16” and the second layer is referred to as a “low acoustic impedance layer 17” for convenience. In the embodiment, the dividing layer 162 is inserted into at least one of the high acoustic impedance layers 16 so as to divide the high acoustic impedance layer 16 into a plurality of sublayers 161 in a laminated direction.

The main role of the dividing layer 162 is to maintain the surface smoothness of sublayers 161 in a good condition and to improve the crystal orientation of an active element such as a resonator provided in an upper layer. Since the high acoustic impedance material is generally hard and has low shape followability, the high acoustic impedance material does not function as the dividing layer. Therefore, the specific acoustic impedance of the dividing layer 162 is desirably equal to or smaller than the specific acoustic impedance of the high acoustic impedance layer 16.

The sublayers 161 and the dividing layer 162 forming the high acoustic impedance layer 16 can be continuously formed by sputtering or the like. By inserting the dividing layer 162 into the high acoustic impedance layer 16, the crystalline states of the sublayers 161 acting as the base can be reset, and the good crystalline state can be maintained as the entirety of the laminated high acoustic impedance layer 16.

The sublayers 161 of the high acoustic impedance layer 16 are made of a material having a high bulk density or bulk modulus, such as tungsten (W), molybdenum (Mo), tantalum dioxide (Ta₂O₅), or zinc dioxide (ZnO). The high acoustic impedance layer 16 may have good thermal conductivity. The dividing layer 162 inserted into the high acoustic impedance layer 16 is made of a material having a lower density or a lower bulk modulus relative to that of the high acoustic impedance layer 16. From the viewpoint of resetting or improving the crystalline states of the sublayers 161, the dividing layer 162 is desirably an amorphous layer.

The dividing layer 162 may be made of amorphous SiO₂, Al₂O₃, WO₃, MoO₃, Si, or the like.

The thickness of the dividing layer 162 is determined by the frequency of the acoustic wave to be reflected by the acoustic multilayer film 18, that is, the resonance frequency of the active element such as the piezoelectric element or the resonator provided on an upper part of the acoustic multilayer film 18. The “upper part” of the acoustic multilayer film 18 refers to a surface of the acoustic multilayer film 18 opposite the support substrate 11. When the wavelength of the acoustic wave propagating through the dividing layer 16 is λ, the thickness of the dividing layer 162 is 1/3000 or more and 1/55 or less of the wavelength λ of the acoustic wave, and preferably 1/3000 or more and 1/66 or less. The basis of this range will be described in detail later with reference to FIG. 5.

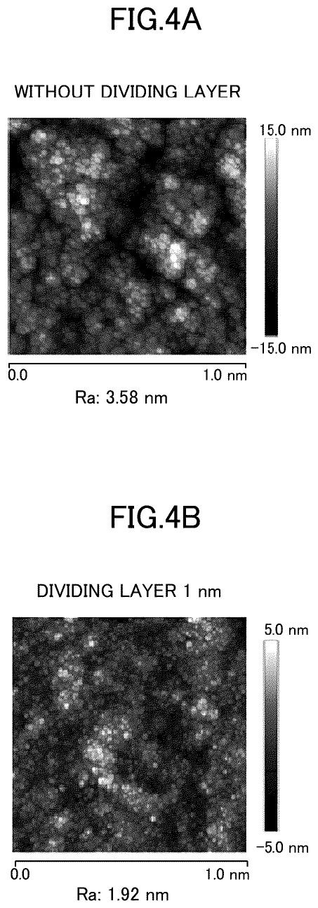

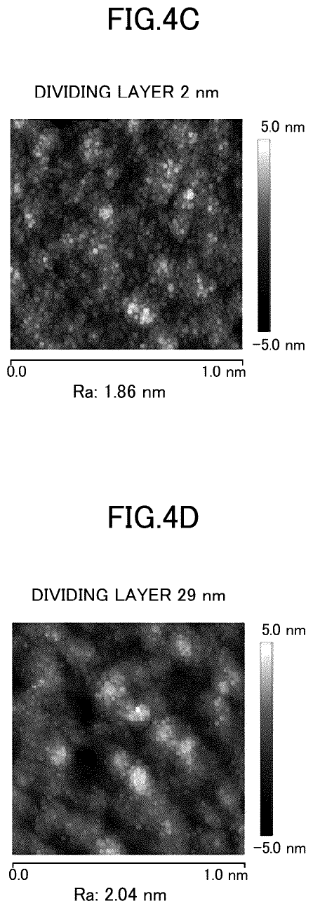

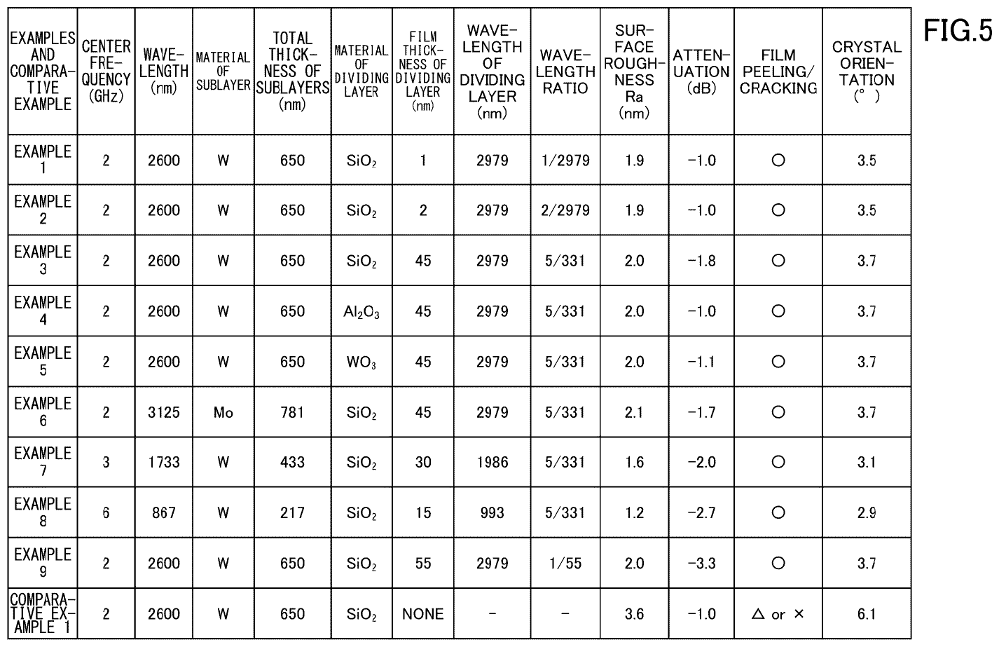

From the viewpoint of maintaining good crystallinity of the active element such as a resonator, the acoustic multilayer film 18 preferably has a surface roughness Ra of 3 nm or less. The surface roughness Ra is a deviation per unit area from the median of the surface roughness of the acoustic multilayer film 18. When the surface roughness Ra exceeds 3 nm, the piezoelectric layer provided on the acoustic multilayer film 18 tends to be less oriented. The disordered orientation of the piezoelectric layer generates an unnecessary vibration mode in the lateral direction, which causes noise. The basis of the surface roughness Ra will be described later with reference to FIGS. 4A to 4D.

The low acoustic impedance layer 17 is made of a material having a bulk density or bulk modulus lower than the high acoustic impedance layer 16, such as SiO₂, Al₂O₃, or alumina silicate glass. The low acoustic impedance layer 17 may be an amorphous layer or an oxide film, such as SiO₂ or Al₂O₃ in which an amorphous phase is dominant.

The support substrate 11 is any substrate that can support the acoustic multilayer film 18. A substrate made of quartz, glass, or the like may be used, or a semiconductor substrate made of silicon (Si) or the like, or an inorganic dielectric substrate made of MgO, sapphire, or the like may be used. Alternatively, a plastic substrate may be used. In the case where a flexible plastic substrate is used as the support substrate 11, polyethylene terephthalate (PET), polyethylene naphthalate (PEN), polycarbonate (PC), an acrylic resin, a cycloolefin polymer, polyimide (PI), thin film glass, or the like may be used.

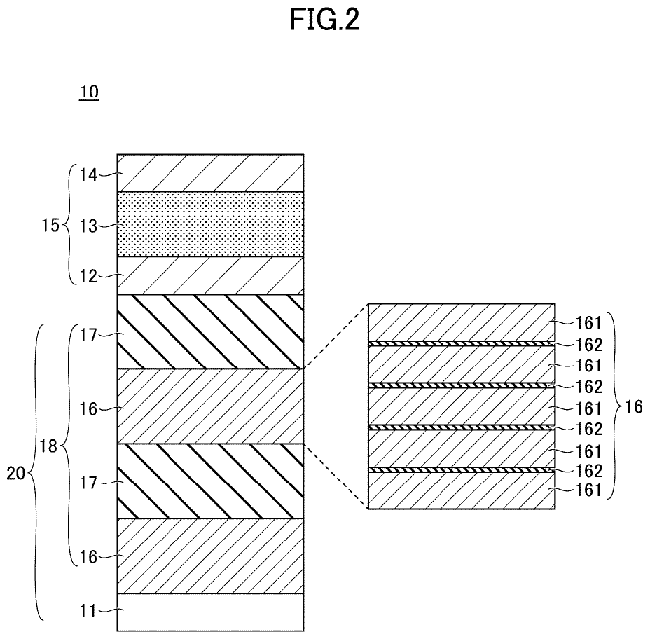

FIG. 2 is a schematic view of the high frequency filter device 10 using the acoustic multilayer film 18 of FIG. 1. The high frequency filter device 10 includes a first electrode layer 12, a second electrode layer 14, and a piezoelectric layer 13 provided between the first electrode layer 12 and the second electrode layer 14, on the surface of the acoustic multilayer film 18 opposite the support substrate 11. The first electrode layer 12, the second electrode layer 14, and the piezoelectric layer 13 form a resonator 15, which is an active element.

The first electrode layer 12 and the second electrode layer 14 are made of conductive materials. For example, as the conductive materials, Mo, W, Pr, Au, Ru, Ir, Al, Cu, or the like may be used. As the material of the piezoelectric layer 13, wurtzite type crystal, perovskite type crystal, or the like can be used. These crystalline materials may be a main component, with a predetermined amount of impurity elements added as sub-components. As wurtzite-type piezoelectric materials, zinc oxide (ZnO), aluminum nitride (AlN), gallium nitride (GaN), and the like can be used.

When the resonance vibration is transmitted from the resonator 15 to the acoustic multilayer film 18, the vibration energy of the resonance is reflected by the acoustic multilayer film 18. The speed at which the vibration wave (acoustic wave) propagates through the high acoustic impedance layer 16 is different from the speed at which the vibration wave propagates through the low acoustic impedance layer 17. By designing the film thickness so that the reflected wave is strengthened by interference at the interface of each layer forming the acoustic multilayer film 18, the vibration energy of resonance can be returned to the incident direction of the acoustic wave without being affected by the support substrate 11.

The resonance energy reflected by the acoustic multilayer film 18 and returned to the resonator 15 is confined between the first electrode layer 12 and the second electrode layer 14, which is extracted as an electric signal by the first electrode layer 12 and the second electrode layer 14. Since at least one of the high acoustic impedance layers 16 is divided into the plurality of sublayers 161 by the dividing layer 162, the surface smoothness of the high acoustic impedance layer 16 is improved and the crystal orientation of the piezoelectric layer 13 is improved; thus, the vibration mode in the film thickness direction is maintained and the high frequency filter device 10 with less noise is provided.

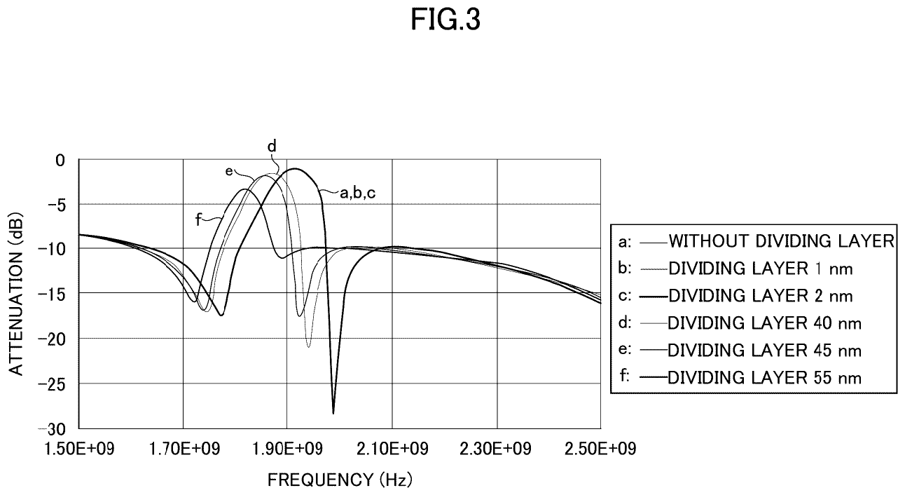

FIG. 3 illustrates a relationship between the film thickness of the dividing layer 162 and the filter characteristics. From the viewpoint of stress relaxation in the acoustic multilayer film 18, when the dividing layer 162 is inserted into the high acoustic impedance layer 16, the filter characteristics may change; thus, the thickness of the dividing layer 162 needs to be appropriately determined. It is desirable that the filter characteristics of the high frequency filter device 10 be not attenuated; however, generally, commercialy available high-frequency filters define the passband to be within the range of approximately −3 dB or less, due to the effect of wiring resistance, and the like, and the allowable range is up to around −3 dB. The filter characteristics are estimated by simulation by varying the thickness of the dividing layer 162.

Assuming 2 GHz as the simulation condition, two pairs of a high acoustic impedance layer 16 of W having a thickness of 655 nm and a low acoustic impedance layer 17 of SiO₂ having a thickness of 725 nm are laminated as the acoustic multilayer film 18 on the silica support substrate 11. Four layers of the dividing layer 162 are inserted into each of the high acoustic impedance layers 16, and the thickness of the dividing layer 162 is changed between 0 nm, 1 nm, 2 nm, 40 nm, 45 nm, and 55 nm. The dividing layer 162 having a thickness of “0 nm” indicates a configuration in which no dividing layer 162 is provided.

When the thickness of the dividing layer 162 is 1 nm and 2 nm, the same filter characteristics as those of the configuration in which no dividing layer 162 is provided are maintained, in conjunction with the surface smoothness of the upper sublayer 161 being improved. Thus, the crystal orientation of the piezoelectric layer 13 disposed over the upper sublayer 161 can be improved. When the thickness of the dividing layer 162 is 40 nm and 45 nm, the attenuation is smaller than 3 dB, and the filter characteristics are not affected substantially. When the thickness of the dividing layer 162 is 55 nm, the attenuation is 3 dB, which is an allowable limit.

The wavelength of the bulk acoustic wave propagating in a medium is defined by (propagation acoustic velocity V [m/s] in the medium)/(resonance frequency F [Hz]). In the case where W is used for the high acoustic impedance layer and SiO₂ is used for the low acoustic impedance layer, the wavelength λ of the bulk acoustic wave propagating in the medium of W is approximately 2600 nm, and the wavelength of the bulk acoustic wave propagating in the medium of SiO₂ is approximately 2979 nm at the resonance frequency of 2 GHz. When the wavelength λ of the acoustic wave propagating through the dividing layer 162 is defined by the propagation acoustic velocity in the medium of the dividing layer 162 and the resonant frequency, the preferable thickness of the dividing layer 162 is approximately 1/3000 or more and 1/50 or less of the wavelength λ, for example. The thickness range of the dividing layer 162 will be described in more detail with reference to FIGS. 4A to 4D, based on actually fabricated samples.

FIGS. 4A to 4D each illustrate a relationship between the thickness of the dividing layer 162 and the surface roughness of the acoustic multilayer film 18. In FIG. 4A, FIG. 4B, FIG. 4C, and FIG. 4D, the thickness of the dividing layer 162 is 0 nm, 1 nm, 2 nm, and 29 nm, respectively. The surface states of the acoustic multilayer film 18 at the respective thicknesses of the dividing layer 162 are illustrated. As described above, the dividing layer 162 is inserted so as to improve the surface smoothness of the upper sublayer 161. Therefore, the thickness range of the dividing layer 162 is studied from the viewpoint of surface smoothness.

As samples, as in the simulation conditions of FIG. 3, two pairs of the high acoustic impedance layer 16 of W having a thickness of 655 nm and the low acoustic impedance layer 17 of SiO₂ having a thickness of 725 nm are laminated on the silica support substrate 11 to form the acoustic multilayer film 18. Four layers of the dividing layer 162 are inserted into each of the high acoustic impedance layers 16, and the thickness of the dividing layer 162 is changed between 0 nm, 1 nm, 2 nm, and 29 nm. The dividing layer 162 having a thickness of “0 nm” corresponds to a configuration in FIG. 4A in which no dividing layer 162 is provided.

The surface of the acoustic multilayer film 18 of each of the samples thus produced is observed in a tapping mode of an atomic force microscope (AFM), and the surface roughness Ra (arithmetic mean roughness) is measured. The measurement range is a region of 1.0 μm×1.0 μm. When the thickness of the dividing layer 162 is 1 nm and 2 nm in FIGS. 4B and 4C, respectively, the surfaces are observed to be uniform from the respective AFM images, and the acoustic multilayer film 18 has a small roughness Ra of 2 nm or less. When the thickness of the dividing layer 162 is 29 nm in FIG. 4D, the surface roughness Ra slightly exceeds 2 nm, but the surface smoothness is maintained.

In contrast, in the sample without the dividing layer 162 as illustrated in FIG. 4A, the surface roughness is observed from the AFM image, and the measured Ra is as large as 3.58 nm. When the acoustic multilayer film 18 has a surface roughness exceeding 3.0 nm, the piezoelectric layer 13 tends to have poor orientation. When the surface roughness of the acoustic multilayer film 18 exceeds 3.5 nm, the full width at half maximum (FWHM) of ZnO(002) measured by X-ray Rocking Curve (XRD) increases by more than 3°. The disordered orientation of the piezoelectric layer 13 generates an unnecessary vibration mode in the lateral direction, resulting in noise. Therefore, the acoustic multilayer film 18 preferably has a surface roughness of 3 nm or less. The relationship between the film thickness of the dividing layer 162 and the surface roughness Ra of the acoustic multilayer film 18 will be described in more detail with reference to FIG. 5.

FIG. 5 illustrates specifications and filter characteristics of the acoustic multilayer film 18 of examples and a comparative example. The specifications of the acoustic multilayer film 18 include the center frequency of resonance (GHz), the wavelength (nm) of the acoustic wave propagating in the sublayers 161 of the high acoustic impedance layer 16, the material of the sublayers 161, the total thickness of one high acoustic impedance layer 16, the thickness of the dividing layer 162, the wavelength (nm) of the acoustic wave propagating in the dividing layer 162, the ratio of the thickness of the dividing layer 162 to the wavelength of the acoustic wave propagating in the dividing layer 162 (for convenience, “wavelength ratio” is used in the drawing), and the surface roughness Ra of the acoustic multilayer film 18. The filter characteristics are represented by attenuation (dB) and crystal orientation (°). As a factor affecting the filter characteristics, the degree of film peeling or cracking is observed.

The crystal orientation is indicated by the FWHM of a peak waveform obtained by measuring the surface of the piezoelectric layer 13 by the XRC method. Specifically, the piezoelectric layer 13 containing ZnO as a main component is formed on the acoustic multilayer film 18 via a metal electrode layer. The crystal orientation is represented by the value of FWHM of the peak waveform of a rocking curve obtained when the fluctuation of the plane orientation from the (002) plane of the ZnO crystal is measured by the XRC method. The ZnO contained in the piezoelectric layer 13 has a wurtzite crystal structure, and the FWHM value indicates the degree of orientation in the c-axis direction of the crystal forming the piezoelectric material. Therefore, the FWHM of the peak waveform of the rocking curve obtained by the XRC method is an index of the c-axis orientation of the piezoelectric layer 13. The smaller the FWHM of the XRC peak waveform, the better the evaluation of the crystal orientation of the piezoelectric layer 13 in the c-axis direction.

The low acoustic impedance layer 17 is fixed to an amorphous SiO₂ having a thickness 725 nm, and the specifications of the high acoustic impedance layer 16 are variously changed to produce a total of 10 samples, including samples of Examples 1 to 9 and Comparative Example 1. The low acoustic impedance layer 17 common to all the samples is formed by RF magnetron sputtering. After the samples are produced, the surface roughness Ra is measured by AFM. Each sample is connected to a network analyzer to measure the attenuation characteristics.

### Example 1

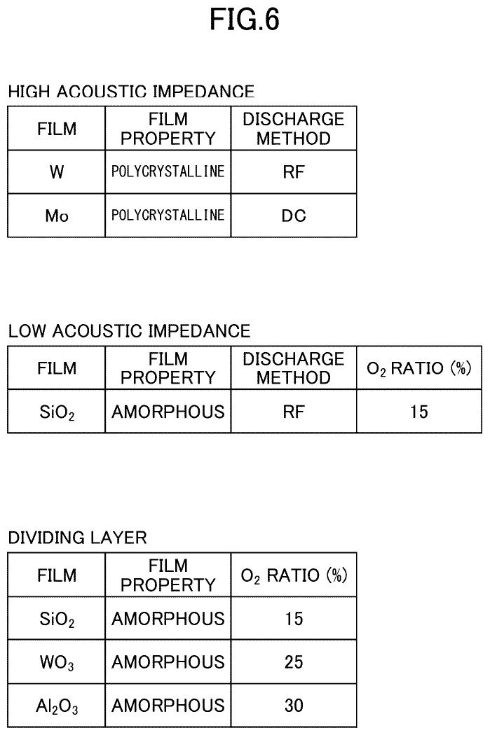

In Example 1, a silicon substrate was used as the substrate, the sublayers 161 of the high acoustic impedance layer 16 were made of W, and the dividing layer 162 were made of amorphous SiO₂. The W layer was formed by RF magnetron sputtering as illustrated in FIG. 6. Under these film forming conditions, a polycrystalline W layer was formed. A total thickness of the sublayers 161 was 650 nm. The SiO₂ dividing layer 162 was formed by RF magnetron sputtering with an O₂ ratio of 15%. Under these conditions, the SiO₂ layers became amorphous. The thickness of the dividing layer 162 was 1 nm, and the total thickness of the high acoustic impedance layer 16 was 650 nm. When the center frequency of the applied high frequency wave was 2 GHZ, the wavelength of the acoustic wave propagating through the W sublayers 161 was approximately 2600 nm, and the wavelength of the acoustic wave propagating through the SiO₂ dividing layer 162 was 2979 nm. The ratio of the thickness of the dividing layer 162 to the wavelength of the acoustic wave at this time was 1/2979. The acoustic multilayer film 18 of the sample of Example 1 had a surface roughness Ra of 1.9 nm, and the attenuation of the filter was −1.0 dB. The surface roughness of the acoustic multilayer film 18 was small, and the attenuation of the filter was also small. The XRC FWHM of the piezoelectric layer 13 formed on the acoustic multilayer film 18 was 3.5°. It is presumed that even when the thickness of the dividing layer 162 is less than 1 nm, for example, the thickness of a few molecular layers, high filter characteristics can be obtained by reducing surface roughness. By inserting the dividing layer 162, the stress of the high acoustic impedance layer 16 was relaxed, and the film peeling and cracking of the acoustic multilayer film 18 could be reduced. The item of film peeling/cracking in FIG. 5 is expressed as “◯”. The mark “◯” indicates that film peeling and cracking were reduced.

### Example 2

In Example 2, the conditions were the same as those of Example 1 except for the thickness of the dividing layer 162. That is, the sublayers 161 of the high acoustic impedance layer 16 were made of W, and a total thickness of the sublayers 161 was 650 nm. The dividing layers 162 were made of amorphous SiO₂ having a thickness of 2 nm. The film forming conditions of the W layer and the SiO₂ layers were the same as those in Example 1. Since the center frequency of the applied high frequency wave was 2 GHZ, the wavelength of the acoustic wave propagating through the W sublayers 161 was approximately 2600 nm, and the wavelength of the acoustic wave propagating through the SiO₂ dividing layer 162 was approximately 2979 nm. The ratio of the thickness of the dividing layer 162 to the wavelength of the acoustic wave was 2/2979. The acoustic multilayer film 18 of the sample of Example 2 had a surface roughness Ra of 1.9 nm, and the attenuation of the filter was −1.0 dB. The surface roughness of the acoustic multilayer film 18 was small, and the attenuation of the filter was also small. The XRC FWHM of the piezoelectric layer 13 formed on the acoustic multilayer film 18 was 3.5°. Furthermore, the stress of the high acoustic impedance layer was relaxed by inserting the dividing layer 162, and the film peeling and cracking of the acoustic multilayer film could be inhibited, and therefore, the item of the film peeling/cracking in FIG. 5 was evaluated as “◯”.

### Example 3

In Example 3, the conditions were the same as those of the Example 1 and Example 2 except for the thickness of the dividing layer 162. That is, the sublayers 161 of the high acoustic impedance layer 16 were made of W and a total thickness of the sublayers 161 was 650 nm. The dividing layers 162 were made of amorphous SiO₂ having a thickness of 45 nm. The film forming conditions of the W layer and the SiO₂ layer were the same as those in Examples 1 and 2. Since the center frequency of the applied high frequency wave was 2 GHz, the wavelength of the acoustic wave propagating through the W sublayers 161 was approximately 2600 nm, and the wavelength of the acoustic wave propagating through the SiO₂ dividing layer 162 was 2979 nm. The ratio of the thickness of the dividing layer 162 to the wavelength of the acoustic wave was 45/2979, that is, 5/331. The acoustic multilayer film 18 of the sample of Example 3 has a surface roughness Ra of 2.0 nm, and the attenuation of the filter was −1.8 dB. The surface roughness of the acoustic multilayer film 18 and the attenuation of the filter were sufficiently within allowable ranges. The XRC FWHM of the piezoelectric layer 13 formed on the acoustic multilayer film 18 was 3.7°, which was within the allowable range. Furthermore, the stress of the high acoustic impedance layer was relaxed by inserting the dividing layer 162, and the film peeling and cracking of the acoustic multilayer film could be inhibited, and therefore, the item of the film peeling/cracking in FIG. 5 was evaluated as “◯”.

### Example 4

In Example 4, the conditions were the same as those of Example 3 except for the material of the dividing layer 162. That is, the sublayers 161 of the high acoustic impedance layer 16 were made of W and a total thickness of the sublayers 161 was 650 nm. The dividing layer 162 was made of amorphous Al₂O₃ having a thickness of 45 nm. The Al₂O₃ layer was formed by RF magnetron sputtering with a O₂ ratio of 30% as illustrated in FIG. 6. Under these conditions, the Al₂O₃ layer became amorphous. The center frequency of the applied high frequency wave was 2 GHz, the wavelength of the acoustic wave propagating through the W sublayers 161 was approximately 2600 nm, and the wavelength of the acoustic wave propagating through the Al₂O₃ dividing layer 162 was 2979 nm. The ratio of the thickness of the dividing layer 162 to the wavelength of the acoustic wave was 45/2979, that is, 5/331. The acoustic multilayer film 18 of the sample of Example 4 had a surface roughness Ra of 2.0 nm, which was the same as that of Example 3, but the attenuation of the filter was −1.0 dB, which was better than that of Example 3. The XRC FWHM of the piezoelectric layer 13 formed on the acoustic multilayer film 18 was 3.7°, which was within the allowable range. Furthermore, the stress of the high acoustic impedance layer was relaxed by inserting the dividing layer 162, and the film peeling and cracking of the acoustic multilayer film could be inhibited, and therefore, the item of the film peeling/cracking in FIG. 5 was evaluated as “◯”.

### Example 5

In Example 5, the conditions were the same as those of Example 3 and Example 4 except for the material of the dividing layer 162. That is, the sublayers 161 of the high acoustic impedance layer 16 were made of W and a total thickness of the sublayers 161 was 650 nm. The dividing layer 162 was made of amorphous WO₃ having a thickness of 45 nm. The WO₃ layers were formed by RF magnetron sputtering with a O₂ ratio of 25%, as illustrated in FIG. 6. Under these conditions, the WO₃ layers became amorphous. The center frequency of the applied high frequency wave was 2 GHZ, the wavelength of the acoustic wave propagating through the W sublayers 161 was approximately 2600 nm, and the wavelength of the acoustic wave propagating through the Al₂O₃ dividing layer 162 was 2979 nm. The ratio of the thickness of the dividing layer 162 to the wavelength of the acoustic wave was 45/2979, that is, 5/331. The surface roughness Ra of the acoustic multilayer film 18 of the sample of Example 5 was 2.0 nm, which was the same as that of Examples 3 and 4. The attenuation of the filter was −1.1 dB, and the filter characteristics similar to those of Example 4 were obtained. The XRC FWHM of the piezoelectric layer 13 formed on the acoustic multilayer film 18 was 3.7°, which was within the allowable range. Furthermore, the stress of the high acoustic impedance layer was relaxed by inserting the dividing layer 162, and the film peeling and cracking of the acoustic multilayer film could be inhibited, and therefore, the item of the film peeling/cracking in FIG. 5 was evaluated as “◯”.

### Example 6

In Example 6, the conditions were the same as those of Example 3 except for the material of the sublayers 161 of the high acoustic impedance layer 16. That is, the sublayers 161 of the high acoustic impedance layer 16 were made of Mo, and the dividing layer 162 was made of amorphous SiO₂ having a width of 45 nm. The Mo sublayers 161 were formed by DC magnetron sputtering as illustrated in FIG. 6. Under these conditions, polycrystalline Mo layers were formed. The total thickness of the sublayers 161 was 781 nm. The center frequency of the applied high frequency wave was 2 GHz, the wavelength of the acoustic wave propagating through the Mo sublayers 161 was approximately 3125 nm, and the wavelength of the acoustic wave propagating through the amorphous SiO₂ dividing layer 162 was 2979 nm. The ratio of the thickness of the dividing layer 162 to the wavelength of the acoustic wave was 45/2979, that is, 5/331. The surface roughness Ra of the acoustic multilayer film 18 of the sample of Example 6 was 2.1 nm, which was close to those of Examples 3 to 5. The attenuation of the filter was −1.7 dB, which was sufficiently within the allowable range. The XRC FWHM of the piezoelectric layer 13 formed on the acoustic multilayer film 18 was 3.7°, which was within the allowable range. Furthermore, the stress of the high acoustic impedance layer was relaxed by inserting the dividing layer 162, and the film peeling and cracking of the acoustic multilayer film could be inhibited, and therefore, the item of the film peeling/cracking in FIG. 5 was evaluated as “◯”.

### Example 7

In Example 7, the frequency to be applied was set to 3 GHz. A silicon substrate was used as a substrate, the sublayers 161 of the high acoustic impedance layer 16 were made of W, and the dividing layer 162 was made of an amorphous SiO₂ having a thickness 30 nm. The total thickness of the W sublayers 161 was 433 nm. In the case of 3 GHZ, the acoustic wave propagating through the W sublayers 161 had a wavelength of approximately 1733 nm, and the acoustic wave propagating through the amorphous SiO₂ dividing layer 162 had a wavelength of 1986 nm. The ratio of the thickness of the dividing layer 162 to the wavelength of the acoustic wave was 30/1986, that is, 5/331. The surface roughness Ra of the acoustic multilayer film 18 of the sample of Example 7 was as small as 1.6 nm. The XRC FWHM of the piezoelectric layer 13 formed on the acoustic multilayer film 18 was as small as 3.1°, and the crystal orientation of the piezoelectric layer 13 was good. The attenuation of the filter was −2.0 dB, which was sufficiently within the allowable range. Furthermore, the stress of the high acoustic impedance layer was relaxed by inserting the dividing layer 162, and the film peeling and cracking of the acoustic multilayer film could be inhibited, and therefore, the item of the film peeling/cracking in FIG. 5 was evaluated as “◯”.

### Example 8

In Example 8, the frequency to be applied was set to 6 GHz. A silicon substrate was used as a substrate, the sublayers 161 of the high acoustic impedance layer 16 were made of W, and the dividing layer 162 was made of an amorphous SiO₂ having a thickness 15 nm. The total thickness of the W sublayers 161 was 217 nm. In the case of 6 GHZ, the acoustic wave propagating through the W sublayers 161 had a wavelength of approximately 867 nm, and the acoustic wave propagating through the amorphous SiO₂ dividing layer 162 had a wavelength of 993 nm. The ratio of the thickness of the dividing layer 162 to the wavelength of the acoustic wave was 15/993, that is, 5/331. The acoustic multilayer film 18 of the sample of Example 8 had a small roughness Ra of 1.2 nm. The XRC FWHM of the piezoelectric layer 13 formed on the acoustic multilayer film 18 was as small as 2.9°, and the crystal orientation of the piezoelectric layer 13 was good. The attenuation of the filter was −2.7 dB, which was within the allowable range. Furthermore, the stress of the high acoustic impedance layer was relaxed by inserting the dividing layer 162, and the film peeling and cracking of the acoustic multilayer film could be inhibited, and therefore, the item of the film peeling/cracking in FIG. 5 was evaluated as “◯”.

### Example 9

In Example 9, the conditions were the same as those of Example 1 except for the thickness of the dividing layer 162. That is, the sublayers 161 of the high acoustic impedance layer 16 were made of W and a total thickness of the sublayers 161 was 650 nm. The dividing layer 162 was made of amorphous SiO₂ having a thickness of 55 nm. The thickness of the dividing layer 162 was the same condition as the characteristics of the simulation of FIG. 3. The center frequency of the applied high frequency wave was 2 GHZ, which was the same as that in the simulation of FIG. 3, the wavelength of the acoustic wave propagating through the W sublayers 161 was approximately 2600 nm, and the wavelength of the acoustic wave propagating through the SiO₂ dividing layer 162 was 2979 nm. The ratio of the thickness of the dividing layer 162 to the wavelength of the acoustic wave was 55/2979, that is, 1/55. The sample of Example 9 had a good roughness Ra of 2.0 nm, and the attenuation of the filter was −3.3 dB, which was within the allowable limit. The XRC FWHM of the piezoelectric layer 13 formed on the acoustic multilayer film 18 was 3.7°, which was close to the allowable limit. It is presumed that increasing of the thickness of the SiO₂ dividing layers larger than 55 nm at a frequency of 2 GHZ would degrade the filter characteristics. Furthermore, the stress of the high acoustic impedance layer was relaxed by inserting the dividing layer 162, and the film peeling and cracking of the acoustic multilayer film could be inhibited, and therefore, the item of the film peeling/cracking in FIG. 5 was evaluated as “◯”.

### Comparative Example 1

In Comparative Example 1, no dividing layer 162 was provided in the high acoustic impedance layer 16. Other conditions were the same as those in Example 1. The high acoustic impedance layer 16 was made of W, and the low acoustic impedance layer was made of SiO₂. The center frequency of the applied high frequency wave was 2 GHZ, the thickness of the high acoustic impedance layers was set to be 650 nm. When no dividing layer 162 was provided, the attenuation of the filter was −1.0 dB, which is good, but the surface roughness of the acoustic multilayer film 18 was 3.6 nm. In this case, the stress generated in the acoustic multilayer film 18 increased, and the possibility of peeling or cracking was high. Further, the XRC FWHM of the piezoelectric layer 13 of the active element 15 was 6.1°, which exceeded the allowable range, and the crystal orientation was poor, so that good resonance characteristics were not expected. Further, since the film stress of the high acoustic impedance layer was very large, and the film peeling and cracking of the acoustic multilayer film was not inhibited, the item of film peeling/cracking in FIG. 5 was evaluated as “Δ” or “x”. The mark “Δ” indicates that the film peeling or cracking was not sufficiently inhibited, and the mark “x” indicates that the film peeling or cracking was not inhibited.

Results of Examples 1 to 9 and Comparative Example 1 indicate that the surface roughness of the acoustic multilayer film 18 can be reduced and the surface smoothness can be maintained by inserting the dividing layer 162 having a thickness of 1/3000 or more and 1/55 or less, more preferably 1/3000 or more and 1/66 or less, of the wavelengths of the acoustic wave corresponding to the operating frequencies into at least one high acoustic impedance layers 16. As illustrated in FIG. 5, when the thickness of the dividing layer 162 inserted into the high acoustic impedance layer 16 was 1 nm or more and 55 nm or less, the thickness of the dividing layer 162 was 1/725 to 1/13 of the film thickness of the low acoustic impedance layer 17 (SiO₂ layer having the thicknesses of 725 nm). The filter characteristics can be maintained within an allowable range, within the film thickness range of the dividing layer 162.

Although the present invention has been described based on the specific embodiments, the present invention is not limited to the above-described configuration examples. For example, the number of pairs of the high acoustic impedance layer 16 and the low acoustic impedance layer 17 that are repeatedly laminated is not limited to two, and a greater number of pairs of the high acoustic impedance layer 16 and the low acoustic impedance layer 17 may be laminated. In this case, the dividing layers 162 are inserted into one or more high acoustic impedance layers 16. The high acoustic impedance layers may be made of Zno, Ta₂O₅, Ru, and Ir, or a composite of these materials, in addition to W and Mo. In this case, the dividing layers are inserted into at least one high acoustic impedance layer. This can inhibit peeling and cracking due to stress, and can excellently maintain high frequency filter characteristics while efficiently reflecting resonance energy generated in an active element when connecting the active element such as a resonator and a piezoelectric element on an acoustic multilayer film. An active element 15 may be provided on a side of the acoustic multilayer film having the above-described configuration opposite the support substrate 11, and the active element 15 may include a first electrode layer 12 provided on the acoustic multilayer film 18, a piezoelectric layer 13 provided on the first electrode layer 12, and a second electrode layer 14 provided on the piezoelectric layer, thereby forming an SMR (Solid Mounted Resonator) type bulk acoustic wave filter device. In this case, the stress of the acoustic multilayer film is also relaxed, and the reliability of the device operation is improved.

The present application claims priority to Japanese Patent Application No. 2022-058814 filed on Mar. 31, 2022. The entire contents of Japanese Patent Application No. 2022-058814 are incorporated herein by reference.

### REFERENCE SIGNS LIST

10 high frequency filter device
11 support substrate
12 first electrode layer
13 piezoelectric layer
14 second electrode layer
15 resonator (active element)
16 high acoustic impedance layer (first layer)
17 low acoustic impedance layer (second layer)
18,28 acoustic multilayer film
20 laminate
161 sublayer
162 dividing layer

1. An acoustic multilayer film comprising:
two or more pairs of a first layer and a second layer, the first layer having a first specific acoustic impedance, the second layer having a specific acoustic impedance lower than the first specific acoustic impedance, and the first layer and the second layer being alternately laminated on a support substrate, wherein at least one of the first layers of the acoustic multilayer film is divided in a laminated direction by a dividing layer.

2. The acoustic multilayer film according to claim 1, wherein the dividing layer inserted in the first layer has a lower acoustic impedance relative to the first specific acoustic impedance.

3. The acoustic multilayer film according to claim 1, wherein two or more layers of the dividing layer are inserted into one of the first layers.

4. The acoustic multilayer film according to claim 1, wherein a film thickness of the dividing layer is 1/725 to 1/1 3 of a film thickness of the second layer.

5. The acoustic multilayer film according to claim 1, wherein a film thickness of the dividing layer is 1/3000 or more and 1/55 or less of a wavelength of a resonant frequency.

6. The acoustic multilayer film according to claim 5, wherein a film thickness of the dividing layer is 1/3000 or more and 1/66 or less of a wavelength of a resonant frequency.

7. The acoustic multilayer film according to claim 1, wherein the acoustic multilayer film has a surface smoothness of 3 nm or less in arithmetic mean roughness.

8. The acoustic multilayer film according to claim 1, wherein the dividing layer is an amorphous layer.

9. The acoustic multilayer film according to claim 8, wherein the dividing layer is a metal oxide or a metal nitride.

10. The acoustic multilayer film according to claim 9, wherein the dividing layer is made of SiO₂, Al₂O₃, WO₃, MoO₃, SiN, or AlN.

11. A high frequency filter device comprising:
the acoustic multilayer film according toclaim 1; and
an active element provided on a side of the acoustic multilayer film opposite the support substrate,
wherein the active element includes a first electrode layer provided on the acoustic multilayer film, a piezoelectric layer provided on the first electrode layer, and a second electrode layer provided on the piezoelectric layer.

12. A bulk acoustic wave filter device comprising:
the acoustic multilayer film according to claim 1; and
an active element provided on a side of the acoustic multilayer film opposite the support substrate,
wherein the active element includes a first electrode layer provided on the acoustic multilayer film, a piezoelectric layer provided on the first electrode layer, and a second electrode layer provided on the piezoelectric layer.
